(19) United States
(12) Patent Application Publication
(10) Pub. No.: US 2024/0170401 A1
(43) Pub. Date: May 23, 2024

(54) SEMICONDUCTOR DEVICE AND METHOD OF FORMING THE SAME

(71) Applicant: Semiconductor Manufacturing International (Shanghai) Corporation, Shanghai (CN)

(72) Inventor: Yichao WU, Shanghai (CN)

(21) Appl. No.: 18/498,359

(22) Filed: Oct. 31, 2023

(30) Foreign Application Priority Data
Nov. 10, 2022 (CN) 202211409159.X

(51) Int. Cl. H01L 23/528; H01L 21/768; H01L 23/48

(52) U.S. Cl. CPC H01L 23/5283; H01L 21/76897; H01L 23/481

(57) ABSTRACT

A semiconductor device includes: a substrate; a plurality of first conductive layers disposed at the substrate, the plurality of first conductive layers being arranged in a first direction, each of the plurality of first conductive layers being parallel to a second direction, and the first direction being perpendicular to the second direction; a conductive plug disposed at the plurality of first conductive layers, the conductive plug being parallel to the first direction, and a bottom surface of the conductive plug being in contact with surfaces of the plurality of first conductive layers; and a second conductive layer disposed at the conductive plug, a bottom surface of the second conductive layer being in contact with a top surface of the conductive plug.

### CROSS-REFERENCE TO RELATED APPLICATION

This application claims priority to Chinese Patent Application No. 202211409159.X, filed on Nov. 10, 2022, the entire content of which is incorporated herein by its reference.

### TECHNICAL FIELD

The present disclosure relates to the technical field of semiconductor manufacturing technology, and more particularly, to a semiconductor device and a method of forming the semiconductor device.

### BACKGROUND

As semiconductor manufacturing technology becomes more and more sophisticated, integrated circuits are also undergoing major changes. The number of components that can be integrated on a same chip has increased from dozens or hundreds initially to millions now. To meet the requirements of circuit density, the manufacturing process of semiconductor integrated circuits uses batch processing technology to form and interconnect various types of complex devices on the substrate to have complete electronic functions.

Generally, a complex semiconductor chip includes a plurality of circuits. The plurality of circuits form an integrated circuit device on a surface of a silicon single crystal substrate. The plurality of circuits distributed on the surface are often interconnected by a complex network of signal paths. Efficient routing of these signals in the integrated circuit device requires formation of multi-level or multi-layer interconnect structures, such as copper-based dual damascene wiring structures. Copper-based interconnects are desirable because they provide high-speed signal transmission between large numbers of transistors on the complex semiconductor chip.

However, in a back-end-of-line (BEOL) interconnect process, as the size of a device shrinks, the size of the interconnect structure of the device is also shrinking, the size of through-holes connecting upper and lower conductive layers is also reduced. As the size of the through-holes reduces, a volume reduction and size effect of conductive plugs formed in the through-holes will cause an interconnection resistance to increase, thereby causing reduced power consumption and degraded electrical performance of the device.

Therefore, how to effectively reduce the resistance of semiconductor devices and improve the electrical performance of the semiconductor devices without increasing the size of the through-holes is an urgent technical problem that needs to be solved.

### SUMMARY

One aspect of the present disclosure provides an electronic device. The electronic device includes: a substrate; a plurality of first conductive layers disposed at the substrate, the plurality of first conductive layers being arranged in a first direction, each of the plurality of first conductive layers being parallel to a second direction, and the first direction being perpendicular to the second direction; a conductive plug disposed at the plurality of first conductive layers, the conductive plug being parallel to the first direction, and a bottom surface of the conductive plug being in contact with surfaces of the plurality of first conductive layers; and a second conductive layer disposed at the conductive plug, a bottom surface of the second conductive layer being in contact with a top surface of the conductive plug.

Another aspect of the present disclosure provides a method of forming a semiconductor device. The method includes: providing a substrate; forming a plurality of first conductive layers at the substrate, the plurality of first conductive layers being arranged in a first direction, each of the plurality of first conductive layers being parallel to a second direction, and the first direction being perpendicular to the second direction; forming a conductive plug at the plurality of first conductive layers, the conductive plug being parallel to the first direction, and a bottom surface of the conductive plug being in contact with surfaces of the plurality of first conductive layers; and forming a second conductive layer at the conductive plug, a bottom surface of the second conductive layer being in contact with a top surface of the conductive plug.

### BRIEF DESCRIPTION OF THE DRAWINGS

FIG. 1 is a schematic structural diagram of an exemplary semiconductor device according to some embodiments of the present disclosure.

FIG. 2 is a top view of the exemplary semiconductor device shown in FIG. 1.

FIGS. 3-15 are schematic structural diagrams showing various stages of a process of forming an exemplary semiconductor device according to some embodiments of the present disclosure.

### DETAILED DESCRIPTION OF THE EMBODIMENTS

In order to make the objectives, technical solutions, and advantages of the present disclosure clearer, the present disclosure will be further described in detail below with reference to the accompanying drawings. Obviously, the described embodiments are only some of the embodiments of the present disclosure, not all of the embodiments. Based on the embodiments of the present disclosure, all other embodiments obtained by those of ordinary skill in the art without creative efforts shall fall within the scope of the present disclosure.

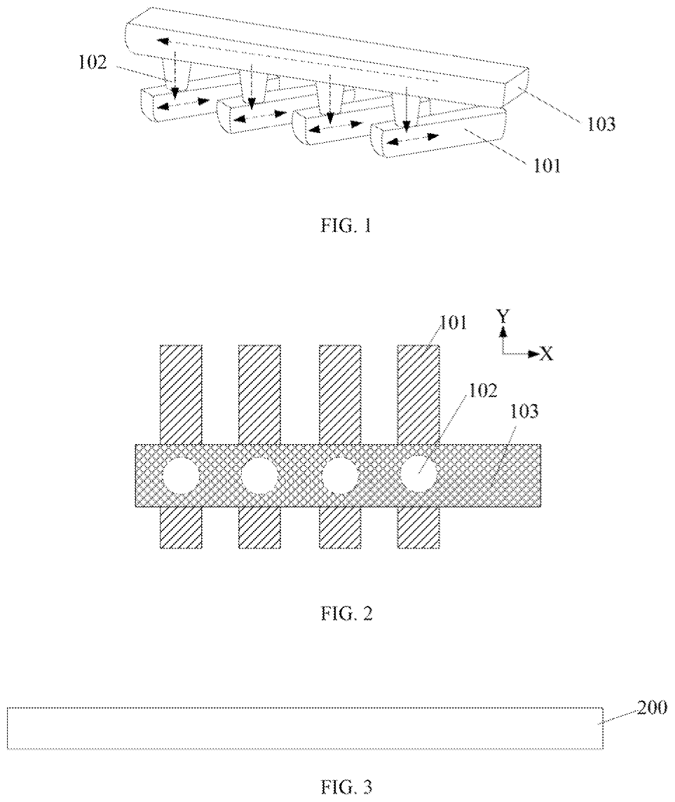

FIG. 1 is a schematic structural diagram of an exemplary semiconductor device according to some embodiments of the present disclosure, while FIG. 2 is a top view of the exemplary semiconductor device shown in FIG. 1.

As shown in FIG. 1 and FIG. 2, the semiconductor device 100 includes a substrate (not shown), a first conductive layer 101 discretely arranged on the substrate along a first direction (X) and extending along a second direction (Y), an interlayer dielectric layer (not shown) disposed at the first conductive layer 101, a plurality of through-holes located in the interlayer dielectric layer with a surface of the first conductive layer 101 being exposed at the bottoms of the plurality of through-holes respectively, a plurality of conductive plugs 102 located in the through-holes respectively, and a second conductive layer 103 disposed above the plurality of conductive plugs 102.

To illustrate interconnection relationship between the first conductive layer, the second conductive layer, and the plurality of conductive plugs, only the first conductive layer, the second conductive layer, and the plurality of conductive plugs are shown in FIGS. 1 and 2.

Dashed lines in FIG. 1 indicate flow directions of electric currents.

Generally, small contact areas between the second conductive layer 103 and the plurality of conductive plugs 102 may lead to a substantial contact resistance of the semiconductor device, thereby resulting in increased power consumption and limiting the performance of the semiconductor device.

The present disclosure provides a method of forming a semiconductor device. The method includes: forming a plurality of first conductive layers on a substrate separately arranged along a first direction, forming a plurality of through-holes in an interlayer dielectric layer disposed at the plurality of first conductive layers simultaneously exposing a surface of each of the plurality of first conductive layers respectively, forming a plurality of conductive plugs inside the plurality of through-holes respectively, and forming a second conductive layer on the interlayer dielectric layer. The plurality of conductive plugs are simultaneously electrically connected to the plurality of first conductive layers, respectively. Adjacent first conductive layers are not separated by the interlayer dielectric layer. The plurality of through-holes distributed on the plurality of first conductive layers can be aggregated into one large effective through-hole, which is equivalent to having a large size conductive plug. The process of forming the plurality of through-holes is simple. A bottom surface of the second conductive layer contacts with a top surface of each of the plurality of conductive plugs, such that contact between the second conductive layer and the plurality of conductive plugs expands from point-to-point to surface-to-surface, and an effective contact area is increased substantially. Thus, an overall resistance of the semiconductor device is effectively reduced, the power consumption of the semiconductor device is reduced, and electrical performance of the semiconductor device is improved.

To make the above objectives, features and advantages of the present disclosure more obvious and understandable, various embodiments of the present disclosure will be described in detail below with reference to the accompanying drawings.

FIGS. 3-15 are schematic structural diagrams showing various stages of a process of forming an exemplary semiconductor device according to some embodiments of the present disclosure. First, referring to FIG. 3, a substrate 200 is provided.

In some embodiments, the substrate 200 includes a substrate (not shown), a device layer (not shown) disposed at the substrate, and an etching stop layer 211 disposed at the device layer.

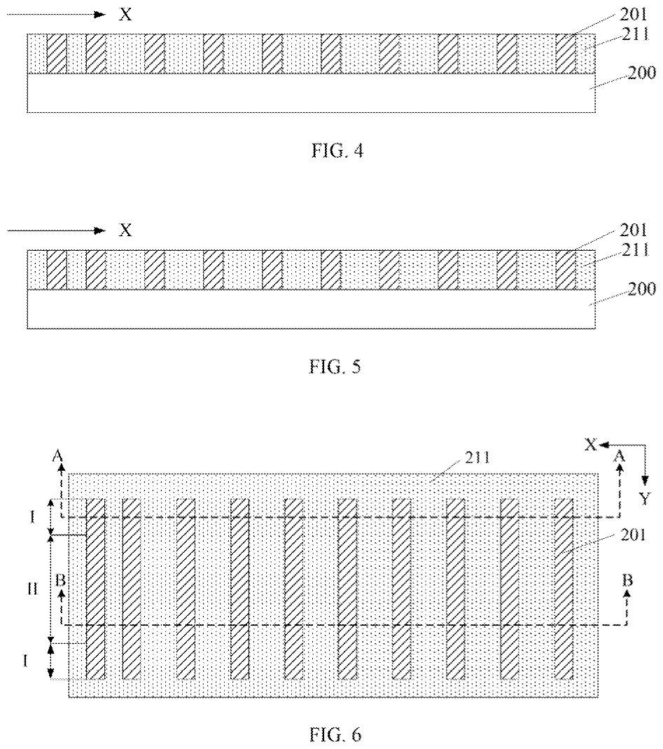

Referring to FIGS. 4 to 6, a plurality of first conductive layers 201 are formed on the substrate 200.

FIG. 6 is a top view of a semiconductor device shown in FIG. 4 and FIG. 5. FIG. 4 is a cross-sectional view of a semiconductor device at A-A of FIG. 6. FIG. 5 is a cross-sectional view of a semiconductor device at B-B of FIG. 6.

The plurality of first conductive layers 201 are arranged along a first direction, and each of the plurality of first conductive layers 201 is parallel to a second direction. The first direction is perpendicular to the second direction.

In some embodiments, X-axis direction is the first direction, and Y-axis direction is the second direction.

In some embodiments, the plurality of first conductive layers 201 are divided into a power line area I and a signal line area II in the second direction (Y).

In some embodiments, the power line area I is mainly used for connecting a main power supply, and the signal line area II is mainly used for signal transmission.

In some embodiments, the plurality of first conductive layers 201 are made of copper.

In some other embodiments, the plurality of first conductive layers 201 may also be made of one or a combination of aluminum, copper, or tungsten.

In some embodiments, forming each of the plurality of first conductive layers 201 includes: etching an etching stop layer 211, forming a contact hole (not shown) in the etching stop layer 211, and filling the contact hole to form a first conductive layer 201.

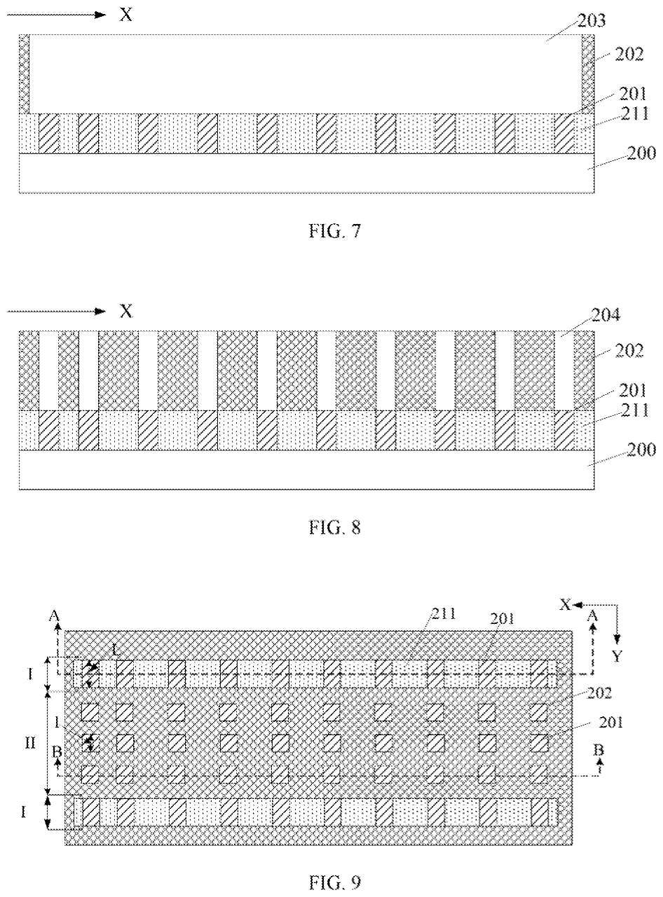

Referring to FIG. 7, an interlayer dielectric layer 202 is formed on the plurality of first conductive layers 201.

FIG. 7 is a cross-sectional view of a semiconductor device at A-A of FIG. 9, and FIG. 9 is a top view of a semiconductor device shown in FIG. 7 and FIG. 8.

In some embodiments, the interlayer dielectric layer 202 is made of silicon nitride.

In some other embodiments, the dielectric layer 202 may also be made of silicon nitride boride, silicon oxynitride, silicon oxynitride, or the like.

In some embodiments, the process of forming the interlayer dielectric layer 202 is a chemical vapor deposition process.

In some other embodiments, the process of forming the interlayer dielectric layer 202 may also be one or more combinations of a physical vapor deposition process, a chemical vapor deposition process, and a physical vapor deposition process.

In some embodiments, process parameters for forming the interlayer dielectric layer 202 by chemical vapor deposition include the followings. Process gases may include oxygen, ammonia (NH₃), and N(SiH₃)₃. A flow rate of oxygen is 20 sccm-10000 sccm, a flow rate of ammonia (NH₃) is 20 sccm-10000 sccm, and a flow rate of N(SiH₃)₃ is 20 sccm˜10000 sccm. A chamber pressure is 0.01˜10 Torr. A chamber temperature is 30° C.˜90° C.

Referring to FIG. 7, the interlayer dielectric layer 202 is etched to form a through hole 203 in the interlayer dielectric layer 202. The through hole 203 extends along the first direction (X) and simultaneously exposes top surfaces of the plurality of first conductive layers 201.

In some embodiments, forming the through hole 203 in the interlayer dielectric layer 202 includes: forming a graphic pattern layer (not shown) on the interlayer dielectric layer 202, the graphic pattern layer having an opening pattern; using the graphic pattern layer as a mask to etch the interlayer dielectric layer 202 and form the through hole 203 in the interlayer dielectric layer 202; and removing the graphic pattern layer.

In some embodiments, forming the through hole 203 only requires adding a photomask. The process is simple and widely used.

Referring to FIG. 8, the interlayer dielectric layer 202 is etched to form a plurality of through-holes 204 in the interlayer dielectric layer 202. A surface of each of the plurality of first conductive layers 201 is exposed at the bottom of each of the plurality of through-holes 204.

FIG. 8 is a cross-sectional view of a semiconductor device at B-B of FIG. 9.

In some embodiments, a size (L) of the through-hole 203 in the second direction is larger than a size (1) of each of the plurality of through-holes 204 in the second direction. Reasons for this arrangement includes the following. The through-hole 203 is used to form power lines, and the plurality of through-holes 204 are used to form signal lines. If the size of the through-hole 203 is enlarged, the volume of a conductive plug subsequently formed and filled in the through-hole 203 will increase. Thus, the subsequently formed power lines will have better electrical performance and enhanced service life.

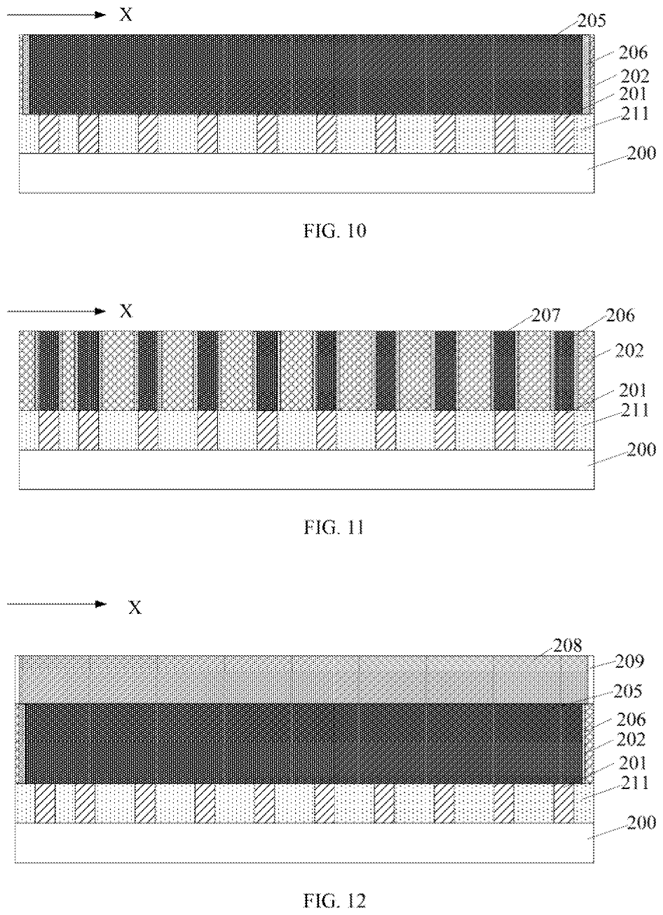

Referring to FIG. 10, a conductive plug 205 is formed in the through-hole 203.

The view direction of FIG. 10 is consistent with the view direction of FIG. 7.

In some embodiments, after the conductive plug 205 is formed in the through-hole 203, the conductive plug 205 appears on top of the plurality of first conductive layers 201. The conductive plug 205 is parallel to the first direction. The bottom of the conductive plug 205 is in contact with the surfaces of the plurality of first conductive layers 201.

In some embodiments, the conductive plug 205 is made of tungsten.

In some other embodiments, the conductive plug 205 is made of one or more combinations of tungsten, cobalt, copper, aluminum, and ruthenium.

In some embodiments, before forming the conductive plug 205, a barrier layer 206 is formed on a sidewall of the through-hole, and the conductive plug 205 is formed on a surface of the barrier layer 206.

In some embodiments, the barrier layer 206 blocks diffusion of atoms in the conductive plug 205 into channels, thereby ensuring the performance of the formed semiconductor device.

In some embodiments, the barrier layer 206 is made of TiN.

In some other embodiments, the barrier layer 206 may also be made of one or more combinations of Ti, TiN, TiO, Ta, and TaN.

Referring to FIG. 11, a conductive plug unit 207 is formed in each of the plurality of through-holes 204.

The view direction of FIG. 11 is consistent with the view direction of FIG. 8.

In some embodiments, the conductive plug unit 207 is made of tungsten.

In some other embodiments, the conductive plug unit 207 may be made of one or more combinations of tungsten, cobalt, copper, aluminum, and ruthenium.

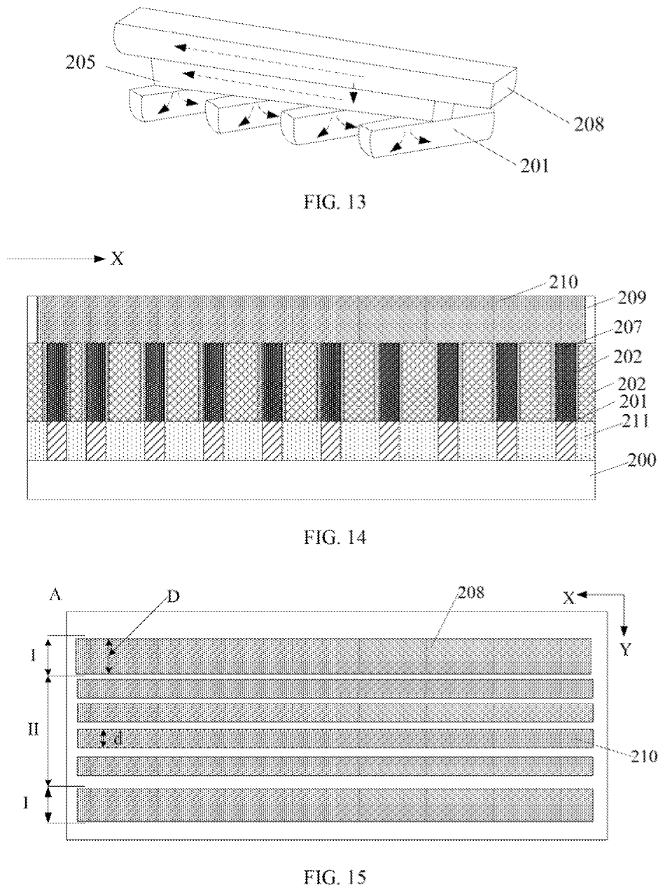

Referring to FIG. 12 and FIG. 13, a second conductive layer 208 is formed on the conductive plug 205. A bottom surface of the second conductive layer 208 is in contact with a top surface of the conductive plug 205.

The view direction of FIG. 12 is consistent with the view direction of FIG. 10. FIG. 13 is a perspective view of a semiconductor device shown in FIG. 12. To illustrate a relationship between the plurality of first conductive layers 201, the conductive plug 205, and the second conductive layer 208, only the plurality of first conductive layers 201, the conductive plug 205, and the second conductive layer 208 are shown in FIG. 13. Other structures of the semiconductor device are omitted.

Dashed lines in FIG. 13 indicate flow directions of electric currents.

In some embodiments, forming the second conductive layer 208 includes: forming a dielectric layer 209 on a surface of the interlayer dielectric layer 202 and a top surface of the conductive plug 205, etching the dielectric layer 209 to expose the top surface of the conductive plug 205, forming a dielectric layer opening (not shown) in the dielectric layer 209, and filling in the dielectric layer opening to form the second conductive layer 208.

In some embodiments, the dielectric layer 209 is made of black diamond.

In some other embodiments, the dielectric layer 209 may also be made of silicon oxide, SiCOH dielectrics, fluorine-doped silicon oxide (FSG), boron-doped silicon oxide (BSG), phosphorus-doped silicon oxide (PSG), boron-phosphorus-doped silicon oxide (BPS G), hydrogenated silsesquioxane, or methylsilsesquioxane, etc.

In some embodiments, the second conductive layer 208 is made of copper.

In some other embodiments, the second conductive layer 208 may also be made of some other conductive materials, such as aluminum and/or tungsten.

In some embodiments, because the through-hole 203 extends along the first direction (X) and exposes the top surfaces of the plurality of first conductive layers 201 at the same time, the conductive plug 205 is formed in the through-hole 203. The through-hole 203 is equivalent to a large through-hole structure that is formed by aggregating the plurality of through-holes 204. As such, on the one hand, the process of forming the through-hole 203 is simplified and production efficiency is improved. On the other hand, the bottom surface of the second conductive layer 208 is in contact with the top surface of the conductive plug 205, and the second conductive layer 208 is arranged parallel to the conductive plug 205, such that the contact between the second conductive layer 208 and the conductive plug 205 expands from the point-to-point contact to the surface-to-surface contact, and the contact area between the second conductive layer 208 and the conductive plug 205 is substantially increased. Thus, the overall contact resistance of the semiconductor device is effectively reduced, the power consumption of the semiconductor device is reduced, and the electrical performance of the semiconductor device is improved.

In some embodiments, the overall resistance of the formed semiconductor device is reduced by 6% to 9%.

In some embodiments, because the through-hole 203 at the power line area I replaces the structure of the plurality of through-holes 204 at the power line area I, a parallel relationship is formed between the second conductive layer 208 and the conductive plug 205 at the power line area I, which replaces a series relationship in the existing technology, thereby substantially increasing current carrying capacity and reducing the resistance at the power line area I, and improving quality and performance of the formed semiconductor device.

In some embodiments, the second conductive layer 208 and the conductive plug 205 are parallel to each other, thereby ensuring that the contact area between the second conductive layer 208 and the conductive plug 205 is maximized.

In some embodiments, the through-hole 203 has a first symmetry axis in the first direction, the second conductive layer 208 has a second symmetry axis in the first direction, and the first symmetry axis overlaps with the second symmetry axis.

Referring to FIG. 14 and FIG. 15, a third conductive layer 210 is formed on the plurality of conductive plug units 207.

FIG. 15 is a top view of a semiconductor device shown in FIG. 14, and the view direction of FIG. 13 is consistent with the view direction of FIG. 11.

In some embodiments, while the dielectric layer 209 is formed on the surface of the interlayer dielectric layer 202 and the top surface of the conductive plug 205, the dielectric layer 209 is also formed on top surfaces of the plurality of conductive plug units 207. A graphic patterning process is performed on the dielectric layer 209 on the top surfaces of the plurality of conductive plug units 207 to form a plurality of openings (not shown) that expose the plurality of conductive plug units 207. A third conductive layer 210 is formed in the plurality of openings.

In some embodiments, the third conductive layer 210 is made of a same material as the second conductive layer 208.

In some embodiments, referring to FIG. 9 and FIG. 15, the through-hole 203 has a first size (L) in the second direction (Y), and the second conductive layer 208 has a second size (D) in the second direction (Y).

In some embodiments, a ratio of the first size (L) over the second size (D) ranges from 50% to 80%. When the ratio of the first size (L) over the second size (D) is less than 50%, reduction effect of the overall resistance is limited. When the ratio of the first size (L) over the second size (D) is greater than 80%, short circuits between adjacent signal lines may occur easily.

In some embodiments, referring to FIG. 15, the second size (D) of the second conductive layer 208 in the second direction (Y) is larger than the second size (d) of the third conductive layer 210 in the second direction (Y). This arrangement has the advantage of reducing resistance and providing sufficient driving current.

Correspondingly, the present disclosure also provides a semiconductor device. The semiconductor device includes a substrate 200, a plurality of first conductive layers 201 disposed at the substrate 200, a conductive plug 205 disposed at the plurality of first conductive layers 201, and a second conductive layer 208 disposed as the conductive plug 205. The plurality of first conductive layers 201 are arranged along a first direction (X). Each of the plurality of first conductive layers 201 is parallel to a second direction (Y). The first direction (X) is perpendicular to the second direction (Y). The conductive plug 205 disposed at the plurality of first conductive layers 201 is parallel to the first direction (X). A bottom surface of the conductive plug 205 is in contact with surfaces of the plurality of first conductive layers 201. A bottom surface of the second conductive layer 208 is in contact with a top surface of the conductive plug 205.

In some embodiments, the conductive plug 205 is disposed at the plurality of first conductive layers 201. The conductive plug 205 is parallel to the first direction (X). The bottom surface of the conductive plug 205 is in contact with the surfaces of the plurality of first conductive layers 201. This structure of the conductive plug 205 aggregates small conductive plugs distributed at each of the plurality of first conductive layers 201 into one large conductive plug. The formation process is simple, and a filling volume of the conductive plug 205 also increases. The second conductive layer 208 is formed at the conductive plug 205. The bottom surface of the second conductive layer 208 is in contact with the top surface of the second conductive layer 205, such that the contact between the second conductive layer 208 and the conductive plug 205 changes from point-to-point contact to surface-to-surface contact, and the contact area is substantially increased. Thus, the overall contact resistance of the semiconductor device is effectively reduced, the power consumption of the semiconductor device is reduced, and the electrical performance of the semiconductor device is improved.

In some embodiments, the plurality of first conductive layers 201 are divided into a power line area I and a signal line area II in the second direction (Y).

In some embodiments, the power line area I is mainly used for connecting a main power supply, and the signal line area II is mainly used for signal transmission.

In some embodiments, the second conductive layer 208 and the conductive plug 205 are parallel to each other, thereby ensuring that the contact area between the second conductive layer 208 and the conductive plug 205 is maximized.

In some embodiments, the semiconductor device also includes an interlayer dielectric layer 202 disposed at the plurality of first conductive layers 201. The interlayer dielectric layer 202 has a through-hole 203 therein. The through-hole 203 extends along the first direction (X) and exposes the top surfaces of the plurality of first conductive layers 201 at the same time.

In some embodiments, the semiconductor device also includes a plurality of through-holes 204 in the interlayer dielectric layer 202. The surface of each of the plurality of first conductive layers 201 is exposed at the bottom of each of the plurality of through-holes 204.

In some embodiments, the size of the through-hole 203 in the second direction is larger than the size of each of the plurality of through-holes 204 in the second direction. The reason for this arrangement includes the following. The through-hole 203 is used to form the power lines, and the plurality of through-holes 204 is used to form the signal lines. If the size of the through-hole 203 is enlarged, the volume of the conductive plug subsequently formed and filled in the through-hole 203 will increase. Thus, the subsequently formed power lines can have better electrical performance and enhanced service life.

In some embodiments, the through-hole 203 has the first size (L) in the second direction (Y), and the second conductive layer 208 has the second size (D) in the second direction (Y).

In some embodiments, the ratio of the first size (L) over the second size (D) ranges from 50% to 80%. When the ratio of the first size (L) over the second size (D) is less than 50%, the reduction effect of the overall resistance is limited. When the ratio of the first size (L) over the second size (D) is greater than 80%, short circuits between adjacent signal lines may occur easily.

In some embodiments, the axis of symmetry of the through-hole 203 in the first direction overlaps with the symmetry axis of the second conductive layer 208 in the first direction.

In some embodiments, the conductive plug 205 is made of one or more combinations of tungsten, cobalt, copper, aluminum, and ruthenium.

In some embodiments, the semiconductor device also includes the barrier layer 206 disposed at the sidewall of the through-hole 203. The conductive plug 205 is disposed at the surface of the barrier layer 206.

In some embodiments, the semiconductor device also includes the plurality of conductive plug units 207 disposed in the plurality of through-holes 204.

In some embodiments, the semiconductor device also includes the third conductive layer 210 disposed at the plurality of conductive plug units 207. The bottom surface of the third conductive layer 210 is in contact with the top surfaces of the plurality of conductive plug units 207 respectively.

In some embodiments, because the through-hole 203 at the power line area I replaces the structure of the plurality of through-holes 204 at the power line area I, the parallel relationship is formed between the second conductive layer 208 and the conductive plug 205 at the power line area I, which replaces the series relationship in the existing technology, thereby substantially increasing current carrying capacity and reducing the resistance at the power line area I, and improving quality and performance of the formed semiconductor device.

The above description of the disclosed embodiments is provided to enable any person skilled in the art to make or use the present application. Various modifications to these embodiments will be readily apparent to those skilled in the art, and the general principles defined herein may be implemented in other embodiments without departing from the spirit or scope of the present disclosure. Therefore, the present disclosure will not be limited to the embodiments shown herein, but is to be accorded the broadest scope consistent with the principles and novel features disclosed herein.

What is claimed is:

1. A semiconductor device, comprising:
a substrate;
a plurality of first conductive layers disposed over the substrate, the plurality of first conductive layers being arranged in a first direction and each extending along a second direction perpendicular to the first direction;
a conductive plug disposed over the plurality of first conductive layers, the conductive plug extending along the first direction, and a bottom surface of the conductive plug being in contact with surfaces of the plurality of first conductive layers; and
a second conductive layer disposed over the conductive plug, a bottom surface of the second conductive layer being in contact with a top surface of the conductive plug.

2. The semiconductor device according to claim 1, wherein:
the second conductive layer extends in parallel to the conductive plug.

3. The semiconductor device according to claim 1, further comprising:
an interlayer dielectric layer disposed over the plurality of first conductive layers, the interlayer dielectric layer having a through-hole therein, and the through-hole extends in the first direction and exposes top surfaces of the plurality of first conductive layers at same time.

4. The semiconductor device according to claim 3, wherein:
the through-hole has a first size in the second direction, and the second conductive layer has a second size in the second direction.

5. The semiconductor device according to claim 4, wherein:
a ratio of the first size over the second size ranges from 50% to 80%.

6. The semiconductor device according to claim 3, wherein:
a symmetry axis of the through-hole in the first direction overlaps with a symmetry axis of the second conductive layer in the first direction.

7. The semiconductor device according to claim 1, wherein:
the conductive plug is made of one or more combinations of tungsten, cobalt, copper, aluminum, and ruthenium.

8. The semiconductor device according to claim 3, further comprising:
a barrier layer disposed at a sidewall of the through-hole, the conductive plug being formed at a surface of the barrier layer.

9. A method of forming a semiconductor device, comprising:
providing a substrate;
forming a plurality of first conductive layers over the substrate, the plurality of first conductive layers being arranged in a first direction and each extending along a second direction perpendicular to the first direction;
forming a conductive plug over the plurality of first conductive layers, the conductive plug extending along the first direction, and a bottom surface of the conductive plug being in contact with surfaces of the plurality of first conductive layers; and
forming a second conductive layer over the conductive plug, a bottom surface of the second conductive layer being in contact with a top surface of the conductive plug.

10. The method to claim 9, wherein:
the second conductive layer extends in parallel to the conductive plug.

11. The method according to claim 9, before forming the conductive plug at the plurality of first conductive layers, further comprising:
forming an interlayer dielectric layer at the plurality of first conductive layers;
etching the interlayer dielectric layer to form the through-hole in the interlayer dielectric layer, the through-hole extending in the first direction and exposing top surfaces of the plurality of first conductive layers at the same time; and
forming the conductive plug in the through-hole.

12. The method according to claim 11, wherein:
the through-hole has a first size in the second direction, and the second conductive layer has a second size in the second direction.

13. The method according to claim 12, wherein:
a ratio of the first size over the second size ranges from 50% to 80%.

14. The method according to claim 11, wherein:
a symmetry axis of the through-hole in the first direction overlaps with a symmetry axis of the second conductive layer in the first direction.

15. The method according to claim 9, wherein:
the conductive plug is made of a material comprising tungsten, cobalt, copper, aluminum, ruthenium, or a combination thereof.

16. The method according to claim 11, further comprising:
forming a barrier layer at a sidewall of the through-hole, the conductive plug being formed on a surface of the barrier layer.

17. The method according to claim 11, wherein forming the through-hole in the interlayer dielectric layer includes:
forming a barrier layer at a sidewall of the through-hole, the conductive plug being formed at a surface of the barrier layer;
forming a graphic pattern layer on the interlayer dielectric layer, the graphic pattern layer having an opening pattern;
using the graphic pattern layer as a mask to etch the interlayer dielectric layer and form the through hole in the interlayer dielectric layer; and
removing the graphic pattern layer.
